(19) United States
(12) Patent Application Publication
(10) Pub. No.: US 2025/0011931 A1
(43) Pub. Date: Jan. 9, 2025

(54) SUBSTRATE PROCESSING APPARATUS, SUBSTRATE PROCESSING METHOD, METHOD OF MANUFACTURING SEMICONDUCTOR DEVICE, AND RECORDING MEDIUM

(71) Applicant: Kokusai Electric Corporation, Tokyo (JP)

(72) Inventors: Shun MATSUI, Toyama-shi (JP); Takashi YOKOGAWA, Toyama-shi (JP); Arito OGAWA, Toyama-shi (JP)

(73) Assignee: Kokusai Electric Corporation, Tokyo (JP)

(21) Appl. No.: 18/894,881

(22) Filed: Sep. 24, 2024

Related U.S. Application Data
(63) Continuation of application No. PCT/JP2022/014081, filed on Mar. 24, 2022.

(51) Int. Cl. C23C 16/455; C23C 16/44; C23C 16/458; H01L 21/02

(52) U.S. Cl. CPC C23C 16/45563; C23C 16/4412; C23C 16/45557; C23C 16/45561; C23C 16/4584; H01L 21/02312; H01L 21/0217

(57) ABSTRACT

There is provided a technique that includes: a processing container including a first region in which a substrate is processed and a second region in which the substrate is not disposed; a first supplier that supplies a processing gas to the first region; a second supplier that supplies an adsorption inhibiting gas to the second region in the processing container, a first supply system capable of supplying the processing gas to the first supplier; a second supply system capable of supplying the adsorption inhibiting gas to the second supplier; and a controller capable of controlling the first supply system and the second supply system to perform: (a) supplying the adsorption inhibiting gas to the second region; and (b) supplying the processing gas to the first region after (a).

### CROSS-REFERENCE TO RELATED APPLICATION

This application is a Bypass Continuation application of PCT International Application No. PCT/JP2022/014081, filed on Mar. 24, 2022, the entire contents of which are incorporated herein by reference.

### BACKGROUND

The present disclosure relates to a substrate processing apparatus, a substrate processing method, a method of manufacturing a semiconductor device, and a recording medium.

### DESCRIPTION OF THE RELATED ART

There is a substrate processing apparatus that performs film formation on a substrate.

### SUMMARY

The present disclosure provides a configuration capable of suppressing film formation on a member in a processing container.

According to one aspect of the present disclosure, there is provided a technique including: a processing container including a first region in which a substrate is processed and a second region in which the substrate is not disposed; a first supplier that supplies a processing gas to the first region of the processing container; a second supplier that supplies an adsorption inhibiting gas to the second region of the processing container; a first supply system capable of supplying the processing gas to the first supplier; a second supply system capable of supplying the adsorption inhibiting gas to the second supplier; and a controller capable of controlling the first supply system and the second supply system to perform: (a) supplying the adsorption inhibiting gas to the second region; and (b) supplying the processing gas to the first region after (a).

### BRIEF DESCRIPTION OF THE DRAWINGS

FIG. 1 is a longitudinal sectional view for explaining a configuration of a substrate processing apparatus according to an embodiment of the present disclosure.

FIG. 2 is a cross-sectional view taken along line A-A of the substrate processing apparatus illustrated in FIG. 1.

FIG. 3 is a block diagram illustrating a control configuration of the substrate processing apparatus according to the embodiment of the present disclosure.

FIG. 4 is a longitudinal sectional view for explaining the configuration of the substrate processing apparatus according to the embodiment of the present disclosure.

### DETAILED DESCRIPTION

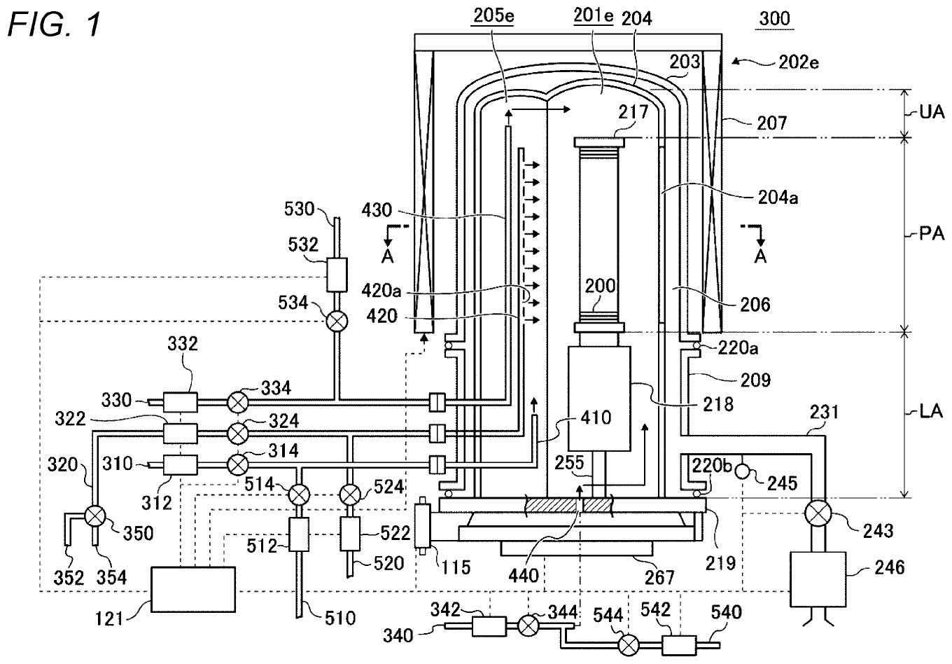

A substrate processing apparatus 10 according to an embodiment of the present disclosure will be described with reference to FIGS. 1 to 3. The drawings used in the following description are all schematic, and dimensional relationships between elements, ratios between elements, and the like illustrated in the drawings do not necessarily coincide with actual ones. In addition, dimensional relationships between elements, ratios between elements, and the like do not necessarily coincide with each other between a plurality of drawings.

As illustrated in FIG. 1, the substrate processing apparatus 10 includes a heater 207 serving as a heating means (heating mechanism, heating system). The heater 207 has a cylindrical shape and is vertically installed by being supported by a heater base (not illustrated) serving as a holding plate.

### (Outer Tube)

Inside the heater 207, an outer tube 203 is disposed constituting a reaction container (processing container) concentrically with the heater 207. The outer tube 203 includes a non-metallic material, for example, quartz (SiO₂), silicon carbide (SiC), or the like, and is formed in a cylindrical shape in which the upper end is closed and the lower end is open. A material such as SiO or SiC is also referred to as a heat-resistant material.

### (Manifold)

Below the outer tube 203, a manifold (inlet flange) 209 is disposed concentrically with the outer tube 203. The manifold 209 includes a metallic material, for example, stainless steel (SUS) or the like, and is formed in a cylindrical shape in which the upper end and the lower end are open. Between an upper end portion of the manifold 209 and the outer tube 203, an O-ring 220a serving as a seal member is provided. The manifold 209 is supported by the heater base, whereby the outer tube 203 is vertically installed.

### (Inner Tube)

Inside the outer tube 203, an inner tube 204 is disposed constituting a reaction container serving as an example of the processing container. The inner tube 204 includes, for example, a non-metallic material, such as quartz (SiO₂) or silicon carbide (SiC), and is formed in a cylindrical shape in which the upper end is closed and the lower end is open. The outer tube 203, the inner tube 204, and the manifold 209 mainly constitute the processing container. In a cylindrical hollow portion (inside the inner tube 204) of the processing container, a process chamber 201e is formed.

The process chamber 201e is configured to be capable of accommodating a wafer 200 serving as an example of a substrate in a state where a plurality of the wafers 200 is arranged in multiple stages in a vertical direction in a horizontal posture by a boat 217 serving as an example of a substrate support to be described later.

In the inner tube 204, a region where the wafer 200 accommodated in the boat 217 is disposed and processed is a process region PA (hereinafter, also referred to as a PA, or a PA region), a region where the wafer 200 is not disposed above the process region PA is an upper substrate-non-disposed region UA (hereinafter, also referred to as a UA, or a UA region), and a region where the wafer 200 is not disposed below the process region PA is a lower substrate-non-disposed region LA (hereinafter, also referred to as a LA, or a LA region).

The PA region is an example of a first region. The UA region and the LA region are examples of a second region. The UA region may be referred to as a second region, and the LA region may be referred to as a third region separately.

In the process chamber 201e, a nozzle 410 that is a pipe-shaped member serving as an example of a second supplier, a nozzle 420 that is a pipe-shaped member serving as an example of a first supplier, and a nozzle 430 that is a pipe-shaped member serving as an example of the second supplier are provided so as to penetrate a side wall of the manifold 209 and the inner tube 204. In the present embodiment, “first supplier”, “second supplier”, and “nozzle” mean members including openings (holes) through which gas is ejected. For that reason, the members do not have to be pipe-shaped members as described in the present disclosure.

### (Nozzle 410)

A gas supply pipe 310 is connected to the nozzle 410.

The gas supply pipe 310 is provided with a mass flow controller (MFC) 312 that is a flow rate control device (flow rate controller) and a valve 314 that is an on-off valve in order from the upstream side. A gas supply pipe 510 that supplies an inert gas is connected to the downstream side of the valve 314 of the gas supply pipe 310. The gas supply pipe 510 is provided with an MFC 512 and a valve 514 in order from the upstream side.

The nozzle 410 is coupled and connected to a distal end portion of the gas supply pipe 310. The nozzle 410 is configured as an L-shaped nozzle, and a horizontal portion thereof is provided so as to penetrate the side wall of the manifold 209 and the inner tube 204. A vertical portion of the nozzle 410 is provided inside a preliminary chamber 205e having a channel shape (groove shape), which is formed so as to protrude outwardly in a radial direction of the inner tube 204 and to extend in the vertical direction, and extends toward the upper side of the apparatus along the inner wall of the inner tube 204 in the preliminary chamber 205e. The opening at the distal end of the nozzle 410 is located inside the LA region, and the nozzle 410 is provided so that the gas also flows in the upward direction and the lateral direction in the LA region. The nozzle 410 is also referred to as the second supplier, and is also referred to as a lower supplier that supplies gas to the LA region out of a plurality of the second suppliers.

From the gas supply pipe 310, an adsorption inhibiting gas is supplied into the process chamber 201e via the MFC 312, the valve 314, and the nozzle 410.

The gas supply pipe 310, the MFC 312, and the valve 314 are examples of a second supply system.

From the gas supply pipe 510, for example, a nitrogen (N₂) gas is supplied as the inert gas into the LA region of the process chamber 201e via each of the MFC 512, the valve 514, and the nozzle 410. Hereinafter, an example of using the N₂ gas as the inert gas will be described, but as the inert gas, for example, a rare gas such as an argon (Ar) gas, a helium (He) gas, a neon (Ne) gas, or a xenon (Xe) gas may be used in addition to the N₂ gas.

### (Nozzle 420)

The nozzle 420 is provided so as to extend to the height of the upper end of the PA region, and a plurality of gas supply holes 420a is provided at positions facing the wafers 200. As a result, a processing gas is laterally (horizontally) supplied from the gas supply holes 420a of the nozzle 420 toward the wafers 200. The plurality of gas supply holes 420a is provided from the lower end to the upper end of the PA region, have the same opening area, and are provided at the same opening pitch. Note that the gas supply holes 420a are not limited to the above-described form. For example, the opening area may be gradually increased from a lower portion to an upper portion of the inner tube 204. As a result, flow rates of the gas supplied from the gas supply holes 420a can be uniformized. The plurality of gas supply holes 420a is an example of a plurality of openings opened in the first region.

A gas supply pipe 320 is connected to the nozzle 420.

A gas supply pipe 352 and a gas supply pipe 354 are connected to an upstream end portion of the gas supply pipe 320 via a valve 350 for gas switching. In the middle of the gas supply pipe 320, a mass flow controller (MFC) 322 that is a flow rate control device (flow rate controller) and a valve 324 that is an on-off valve are provided in order from the upstream side. A gas supply pipe 520 that supplies the inert gas is connected to the downstream side of the valve 324 of the gas supply pipe 320. The gas supply pipe 520 is provided with an MFC 522 and a valve 524 in order from the upstream side.

The gas supply pipe 320, the mass flow controller (MFC) 322, the valve 324, the gas supply pipe 352, and the gas supply pipe 354 are examples of a first supply system.

A source gas as a processing gas is supplied to the gas supply pipe 352, and a reactant gas as a processing gas is supplied to the gas supply pipe 354.

### (Nozzle 430)

A gas supply pipe 330 is connected to the nozzle 430.

The gas supply pipe 330 is provided with a mass flow controller (MFC) 332 that is a flow rate control device (flow rate controller) and a valve 334 that is an on-off valve in order from the upstream side. A gas supply pipe 530 that supplies the inert gas is connected to the downstream side of the valve 334 of the gas supply pipe 330. The gas supply pipe 530 is provided with an MFC 532 and a valve 534 in order from the upstream side.

From the gas supply pipe 330, the adsorption inhibiting gas is supplied into the process chamber 201e via the MFC 332, the valve 334, and the nozzle 430.

The gas supply pipe 330, the MFC 332, and the valve 334 are examples of the second supply system.

From the gas supply pipe 530, for example, the nitrogen (N₂) gas is supplied as the inert gas into the UA region of the process chamber 201e via each of the MFC 532, the valve 534, and the nozzle 430. The nozzle 430 is also referred to as the second supplier, and is also referred to as an upper supplier that supplies gas to the UA region out of the plurality of second suppliers.

The nozzle 430 is coupled and connected to a distal end portion of the gas supply pipe 330. The nozzle 430 is configured as an L-shaped nozzle, and a horizontal portion thereof is provided so as to penetrate the side wall of the manifold 209 and the inner tube 204. A vertical portion of the nozzle 430 is provided inside the preliminary chamber 205e of the inner tube 204, and extends toward the upper side of the apparatus along the inner wall of the inner tube 204 in the preliminary chamber 205e. The opening at the distal end of the nozzle 430 is located inside the upper substrate-non-disposed region UA, and supplies the adsorption inhibiting gas or the inert gas into the upper substrate-non-disposed region UA. The nozzle 430 is preferably provided so as to blow the gas onto the ceiling of the inner tube 204.

In a method of supplying the processing gas in the present embodiment, the gas is transferred via the nozzle 420 disposed in the preliminary chamber 205e in an annular vertically long space defined by the inner wall of the inner tube 204 and end portions of the plurality of wafers 200. Then, the gas is ejected into the inner tube 204 from the plurality of gas supply holes 420a provided at positions facing the wafers 200 of the nozzle 420. More specifically, the gas is ejected in a direction parallel to surfaces of the wafers 200 by the gas supply holes 420a of the nozzle 420.

An exhaust hole (exhaust port) 204a is a through-hole that is formed at a position facing the nozzle 420 in the side wall of the inner tube 204 and is, for example, a slit-shaped through-hole that is provided so as to be elongated in the vertical direction. The gas, which has been supplied into the process chamber 201e from the gas supply holes 420a of the nozzle 420 and has flowed on the surfaces of the wafers 200, flows into an exhaust path 206 including a gap formed between the inner tube 204 and the outer tube 203 through the exhaust hole 204a. Then, the gas that has flowed into the exhaust path 206 flows into an exhaust pipe 231 and is discharged to the outside of a processing furnace 202e.

The exhaust hole 204a is provided at a position facing the plurality of wafers 200, and the gas supplied from the gas supply holes 420a to the vicinity of the wafers 200 in the process chamber 201e flows in the horizontal direction and then flows into the exhaust path 206 through the exhaust hole 204a. The exhaust hole 204a is not limited to being configured as a slit-shaped through-hole and may be formed by a plurality of holes.

The manifold 209 is provided with the exhaust pipe 231 that exhausts an atmosphere in the process chamber 201e. To the exhaust pipe 231, a pressure sensor 245 serving as a pressure detecting device (pressure detector) that detects a pressure in the process chamber 201e, an auto pressure controller (APC) valve 243, and a vacuum pump 246 serving as a vacuum exhaust are connected in order from the upstream side. The APC valve 243 can perform vacuum exhaust and vacuum exhaust stop in the process chamber 201e by opening and closing the valve in a state where the vacuum pump 246 is operated, and furthermore, can regulate a pressure in the process chamber 201e by adjust a degree of valve opening in a state where the vacuum pump 246 is operated. The exhaust hole 204a, the exhaust path 206, the exhaust pipe 231, the APC valve 243, and the pressure sensor 245 mainly constitute an exhaust system. The vacuum pump 246 may be considered to be included in the exhaust system. The exhaust pipe 231, the APC valve 243, and the vacuum pump 246 are examples of an exhauster, and the APC valve 243 and the vacuum pump 246 are controlled by a controller 121 described later.

A seal cap 219 serving as a furnace lid capable of airtightly closing a lower end opening of the manifold 209 is provided below the manifold 209. The seal cap 219 is configured to be brought into contact with the lower end of the manifold 209 from a lower side in the vertical direction. The seal cap 219 includes a metallic material, for example, SUS or the like, and is formed in a disk shape. On the upper surface of the seal cap 219, an O-ring 220b is provided serving as a seal member that is in contact with the lower end of the manifold 209.

On an opposite side from the process chamber 201e with respect to the seal cap 219, a rotator 267 is installed that rotates the boat 217 that accommodates the wafers 200. A rotation shaft 255 of the rotator 267 penetrates the seal cap 219 and is connected to the boat 217. The rotation shaft 255 is an example of a support shaft. The rotation shaft 255 includes a metallic material such as SUS or a non-metallic material such as quartz. The rotator 267 is configured to rotate the wafers 200 by rotating the boat 217. The seal cap 219 is configured to be lifted and lowered in the vertical direction by a boat elevator 115 serving as an elevating mechanism vertically installed outside the outer tube 203. The boat elevator 115 is configured to be capable of loading the boat 217 into the process chamber 201e and unloading the boat 217 out of the process chamber 201e by lifting and lowering the seal cap 219. The boat elevator 115 is configured as a transfer device (transfer mechanism) that transfers the boat 217 and the wafers 200 accommodated in the boat 217 to the inside and the outside of the process chamber 201e.

The boat 217 serving as the substrate support is configured so that a plurality of, for example, 25 to 200 wafers 200 are arranged at intervals in the vertical direction in a horizontal posture and in a state where the centers thereof are aligned with each other. The boat 217 may include a non-metallic material, for example, quartz, SiC, or the like, or may include a metallic material such as SUS. Below the boat 217, a heat insulator 218 is provided including a non-metallic material, for example, quartz, SiC, or the like. With this configuration, heat from the heater 207 is less likely to be transferred to the seal cap 219 side. The heat insulator 218 has a configuration in which, for example, heat insulating plates formed in plate shapes are provided in multiple stages (not illustrated) in a horizontal posture. Note that the present embodiment is not limited to the above-described form. For example, the heat insulator 218 may include a heat insulating tube configured as a tubular member including a non-metallic material such as quartz or SiC.

Since the lower substrate-non-disposed region LA is a region where the heat insulator 218 is disposed, the lower substrate-non-disposed region LA can be rephrased as a heat insulating region.

In the present disclosure, the metallic material is a material containing a transition metal of Groups 3 to 11 of the periodic table and a material containing a half material of Group 14 as a main component. In the present disclosure, the metallic material may mean a material having a metallic property. Here, the metallic property means, for example, having conductivity. The non-metallic material is a material containing an element of Groups 14 to 16 of the periodic table. For example, the material is a material containing at least one or more of an oxide, a nitride, and a carbide. In the present disclosure, the non-metallic material may be referred to as a heat-resistant material, but the metallic material may also have heat resistance.

### (Gas Ejection Hole of Seal Cap 219)

In the seal cap 219, a gas ejection hole 440 penetrating the seal cap 219 in the vertical direction is formed at a position closer to the rotation shaft 255 that rotates the boat 217 than an outer peripheral portion of the inner tube 204. The gas ejection hole 440 supplies the adsorption inhibiting gas or the inert gas to be described later to the vicinity of the rotation shaft 255 in the LA region. The gas ejection hole 440 is an example of the second supplier and an example of a support-shaft-side supplier.

A gas supply pipe 340 is connected to the gas ejection hole 440.

The gas supply pipe 340 is provided with a mass flow controller (MFC) 342 that is a flow rate control device (flow rate controller) and a valve 344 that is an on-off valve in order from the upstream side. A gas supply pipe 540 that supplies the inert gas is connected to the downstream side of the valve 344 of the gas supply pipe 340. The gas supply pipe 540 is provided with an MFC 542 and a valve 544 in order from the upstream side.

From the gas supply pipe 340, the adsorption inhibiting gas is supplied into the LA region of the process chamber 201e via the MFC 342, the valve 344, and the gas ejection hole 440.

The gas supply pipe 340, the MFC 342, and the valve 344 are examples of the second supply system.

From the gas supply pipe 540, for example, the nitrogen (N₂) gas is supplied as the inert gas into the LA region of the process chamber 201e via each of the MFC 542, the valve 544, and the gas ejection hole 440.

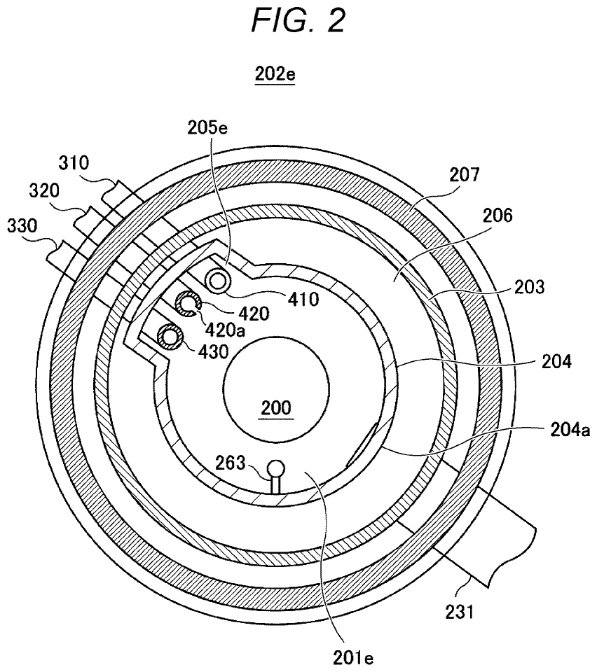

As illustrated in FIG. 2, the inside of the inner tube 204 is configured such that a temperature sensor 263 serving as a temperature detector is installed and a temperature in the process chamber 201e has a desired temperature distribution by regulating an amount of energization to the heater 207 on the basis of temperature information detected by the temperature sensor 263. The temperature sensor 263 is formed in an L-shape similarly to the nozzles 410 and is provided along the inner wall of the inner tube 204.

### (Configuration of Controller 121)

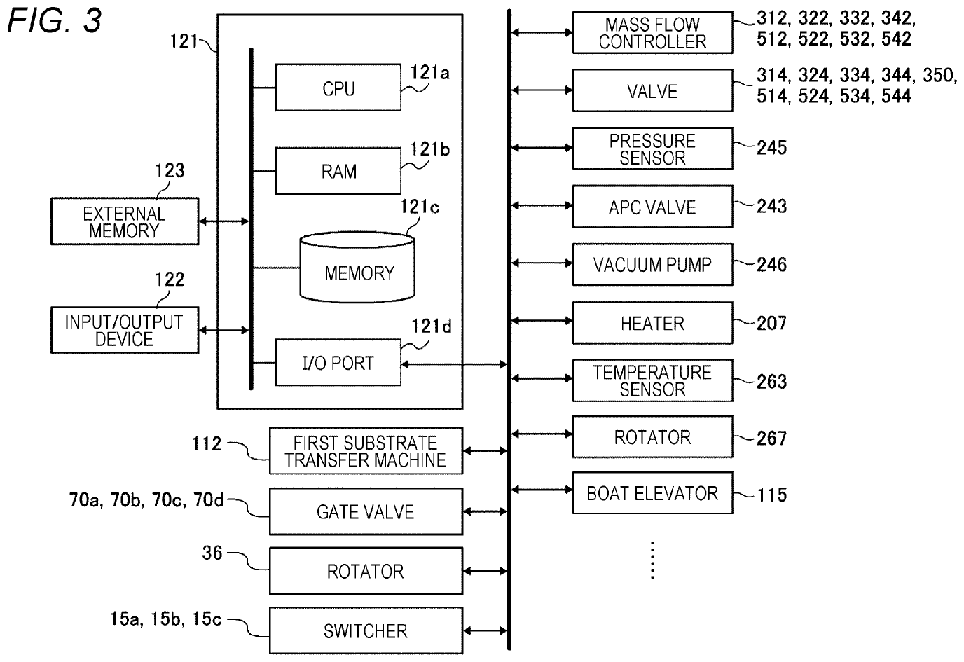

As illustrated in FIG. 3, the controller 121 that is an example of a controller (control means) is configured as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus. An input/output device 122 formed as, for example, a touch panel or the like is connected to the controller 121.

The memory 121c includes, for example, a flash memory, a hard disk drive (HDD), or the like. The memory 121c readably stores a control program that controls an operation of the substrate processing apparatus, a process recipe in which a procedure, a condition, and the like of a method of manufacturing a semiconductor device described later are described, and the like. The process recipe is a combination formed so as to cause the controller 121 to execute steps in the method of manufacturing a semiconductor device described later to obtain a predetermined result, and functions as a program. Hereinafter, the process recipe, the control program, and the like are also collectively and simply referred to as a program. In the present specification, a term “program” may include only the process recipe alone, only the control program alone, or a combination of the process recipe and the control program. The RAM 121b is formed as a memory area (work area) in which programs, data, and the like, read by the CPU 121a are temporarily held.

The I/O port 121d is connected to a first substrate transfer machine 112, gate valves 70a to 70d, a rotator 36, switchers 15a to 15c, the MFCs 312, 322, 332, 342, 512, 522, 532, and 542, the valves 314, 324, 334, 344, 350, 514, 524, 534, and 544, the pressure sensor 245, the APC valve 243, the vacuum pump 246, the heater 207, the temperature sensor 263, the rotator 267, the boat elevator 115, and the like.

The CPU 121a is configured to read the control program from the memory 121c to execute the control program and to read a recipe, and the like, from the memory 121c in response to an input of an operation command from the input/output device 122, and the like.

The CPU 121a is configured to be capable of controlling sections of the apparatus according to the contents of the read recipe.

The CPU 121a is configured to be capable of controlling: flow rate regulation operations of various gases by the MFCs 312, 322, 332, 342, 512, 522, 532, and 542; open and close operations of the valves 314, 324, 334, 344, 350, 514, 524, 534, and 544; open and close operations of the APC valve 243, and a pressure regulation operation based on the pressure sensor 245 by the APC valve 243; a temperature regulation operation of the heater 207 based on the temperature sensor 263; start and stop of the vacuum pump 246; rotation and rotation speed adjustment operations of the boat 217 by the rotator 267; lifting and lowering operations of the boat 217 by the boat elevator 115; an accommodating operation of the wafers 200 into the boat 217; and the like, according to the content of the read recipe.

That is, the controller 121 is configured to be capable of controlling the boat elevator 115, the rotator 267, a gas supply system and a gas exhaust system of the processing furnace 202e, and the like.

The controller 121 can be configured by installing the above-described program stored in an external memory (for example, a magnetic tape, a magnetic disk such as a flexible disk or a hard disk, an optical disk such as a CD or a DVD, a magneto-optical disk such as an MO disk, or a semiconductor memory such as a USB memory or a memory card) 123 in a computer. The memory 121c and the external memory 123 are configured as computer-readable recording media. Hereinafter, the memory 121c and the external memory 123 are collectively and simply referred to as a recording medium. In the present specification, a term “recording medium” may include only the memory 121c alone, only the external memory 123 alone, or both of these. A program may be provided to a computer using a communication means such as the Internet or a dedicated line without using the external memory 123.

### (Substrate Processing Step)

Hereinafter, a step of forming a SiN film on the wafer 200 will be described as an example of a step of a semiconductor device (device) manufacturing step. In the following description, operations of the sections constituting the substrate processing apparatus 10 are controlled by the controller 121.

### (Wafer Loading)

In the substrate processing apparatus 10 of the present embodiment, when the boat 217 is charged with the plurality of wafers 200 (wafer charge), the boat 217 supporting the plurality of wafers 200 is lifted and loaded into the process chamber 201e (boat load) by the boat elevator 115. In this state, the seal cap 219 closes a lower end opening of the outer tube 203 through the O-ring 220.

Next, the inside of the process chamber 201e is vacuum-exhausted by the vacuum pump 246 so as to have a desired pressure (degree of vacuum). At this time, the pressure in the process chamber 201e is measured by the pressure sensor 245, and the APC valve 243 is feedback-controlled (pressure regulation) on the basis of the measured pressure information. The inside of the process chamber 201e is heated by the heater 207 to have a desired temperature. At this time, the amount of energization to the heater 207 is feedback-controlled on the basis of temperature information detected by the temperature sensor 263 so that the inside of the process chamber 201e has a desired temperature distribution (temperature regulation). The heating in the process chamber 201e by the heater 207 is continuously performed at least until processing on the wafers 200 is completed.

### (Source Gas Supply)

Next, the source gas is caused to flow into the process chamber 201e of the inner tube 204 to process the wafers 200. The source gas is supplied into the process chamber 201e from the gas supply holes 420a of the nozzle 420, and is exhausted from the exhaust pipe 231. At this time, the source gas is supplied to the wafers 200. In parallel with this, the valve 524 is opened to cause the inert gas such as the N₂ gas to flow into the gas supply pipe 520. The N₂ gas flowing through the gas supply pipe 520 is supplied into the process chamber 201e together with the source gas, and is exhausted from the exhaust pipe 231.

As the source gas, for example, a chlorosilane gas can be used such as a monochlorosilane (SiH₃Cl, abbreviated as MCS) gas, a dichlorosilane (SiH₂Cl₂, abbreviated as DCS) gas, a trichlorosilane (SiHCl₃, abbreviated as TCS) gas, a tetrachlorosilane (SiCl₄, abbreviated as STC) gas, a hexachlorodisilane (Si₂Cl₆, abbreviated as HCDS) gas, or an octachlorotrisilane (Si₃Cl₈, abbreviated as OCTS) gas. One or more of these gases can be used as the source gas.

As the source gas, in addition to the chlorosilane gas, it is also possible to use, for example, a fluorosilane gas such as a tetrafluorosilane (SiF₄) gas or a difluorosilane (SiH₂F₂) gas, a bromosilane gas such as a tetrabromosilane (SiBr₄) gas or a dibromosilane (SiH₂Br₂) gas, or an iodosilane gas such as a tetraiodosilane (SiI₄) gas or a diiodosilane (SiH₂I₂) gas. One or more of these gases can be used as the source gas.

In addition to such a gas containing a silicon (Si) element and a halogen, a gas containing a metal element and a halogen may be used. As the gas containing a metal element and a halogen element, it is possible to use, for example, a titanium tetrachloride (TiCl₄) gas, a molybdenum chloride (MoCl₅) gas, a hafnium chloride (HfCl₄) gas, a zirconium chloride (ZrCl₄) gas, or an aluminum chloride (AlCl₃) gas. The source gas can be selected according to a type of a film to be formed on the wafer 200. In the present disclosure, an example in which a silicon nitride film containing Si and N is formed on the wafer 200 will be described.

After the processing of the wafers 200 is performed by supplying the source gas, the residual gas in the process chamber 201e is removed, and thereafter, the reactant gas (for example, a NH₃ gas or the like) is caused to flow into the process chamber 201e from the nozzle 420. In parallel with this, the valve 534 is opened to cause the N₂ gas to flow into the gas supply pipe 530. The reactant gas and the N₂ gas supplied into the process chamber 201e are exhausted from the exhaust pipe 231.

As a result, a SiN film containing Si and N is formed on a SiN layer on the wafer 200. A cycle of supplying the source gas and the reactant gas is performed one or more times, whereby a SiN film having a predetermined thickness can be formed.

### (Adsorption Inhibiting Gas Supply Step: Film Formation Suppression Processing by Adsorption Inhibiting Gas)

Meanwhile, in a case where film formation is performed on the wafer 200, the source gas may be adsorbed to a member on which film formation is not desired to be performed, and a film may be formed on the member on which film formation is not desired to be performed. Here, the member on which film formation is not desired to be performed is a member (place) other than the wafer 200, and examples thereof include the inner surface of the inner tube 204, the seal cap 219, the rotation shaft 255, and the like.

For this reason, in the substrate processing apparatus 10 of the present embodiment, before a step of performing predetermined film formation on the wafer 200, the adsorption inhibiting gas is supplied to members such as the inner tube 204, the seal cap 219, and the rotation shaft 255 to modify surface of the members, in other words, an adsorption inhibiting component of the adsorption inhibiting gas is adsorbed to the surface of the members, whereby adsorption of the source gas to the surfaces of these members is suppressed. As a result, unintended film formation on the surfaces of these members can be suppressed.

As the adsorption inhibiting gas, an organic substance and an inorganic substance are conceivable. The inorganic substance has higher heat resistance than the organic substance.

Thus, as an example, in a case where film formation is performed at a high temperature of 500° C. or higher, a halogen-based gas that is an inorganic material and contains at least one or more of F, Cl, Br, and I can be used as the adsorption inhibiting gas. Specifically, there are a fluorine (F₂) gas, a chlorine (Cl₂) gas, a bromine (Br₂) gas, an iodine (I₂) gas, a hydrogen chloride (HCl) gas, a hydrogen fluoride (HF) gas, a hydrogen bromide (HBr) gas, a hydrogen iodide (HI) gas, a chlorine trifluoride (ClF₃) gas, a nitrogen trifluoride (NF₃) gas, a tungsten hexafluoride (WF₆) gas, and the like. In the present disclosure, the adsorption inhibiting gas is also referred to as a modifying gas or a surface modifying gas because the adsorption inhibiting gas improves characteristics of the surface of a target member. The halogen-based gas is also referred to as a halogen-based adsorption inhibiting gas or a halogen-based modifying gas. As the halogen-based gas, a material having a relatively large molecular polarity is preferably used. For example, the gas is a gas containing a halogen element and an element other than the halogen element, such as HCl or WF₆. A molecule of such a gas having high molecular polarity is characterized by being easily adsorbed. By using a material having a relatively large molecular polarity, it is possible to increase an amount of adsorption of a part (for example, a halogen element) of the molecule of the halogen-based gas to the member. Among the halogen-based gases, those having particularly high binding energy are preferable. In addition, a material having high electronegativity is preferable. By using a gas having high binding energy, it is possible to strengthen adsorption (binding to the surface) force to the member, and it is possible to suppress desorption of the molecule of the adsorption inhibiting gas, and the ligand during the processing of the wafers 200. In addition, by using a material having a high electronegativity, it is possible to suppress adsorption of the source gas by using the source gas having the same polarity as the polarity of the molecule or ligand of the adsorption inhibiting gas.

As the adsorption inhibiting gas of the organic substance, a gas containing a hydrocarbon or a gas forming a self-assembled monolayer (SAM) can be used. As these gases, for example, general formula R—PO₃H, hexamethyldisilazane (HMDS), and the like can be used. The general formula R—PO₃H (R is a group containing an alkyl group) includes specifically the following three.

CH₃(CH₂)₆CH₂—P(O)(OH)₂ (1)

CF₃(CF₂)₅CH₂—CH₂—P(O)(OH)₂ (2)

CH₃(CH₂)₁₆CH₂)—P(O)(OH)₂ (3)

The adsorption inhibiting gas of the organic substance and the adsorption inhibiting gas of the inorganic substance may be separately used according to processing conditions of the wafers 200. In addition, both the organic substance adsorption inhibiting gas and the inorganic substance adsorption inhibiting gas may be used, as necessary.

A type of the adsorption inhibiting gas is appropriately selected according to a material that adsorbs the adsorption inhibiting component.

For example, in a case where the adsorption inhibiting component is adsorbed to a metal member, R—PO₃H can be used as an example of the adsorption inhibiting gas that is easily adsorbed to the metal member.

In a case where the adsorption inhibiting component is adsorbed to a quartz member, ClF₃, WF₆, HCl, HMDSN, or the like can be used as an example of the adsorption inhibiting gas that is easily adsorbed to the quartz member.

As an example, when a halogen (for example, F) is adsorbed to the quartz member, Cl contained in the Si₂Cl₆ gas as the source gas becomes a repulsion factor because Cl is an electrically negative ligand with F on the quartz member, and is hardly adsorbed to the quartz member having F adsorbed to the surface. In a case where a gas containing a methyl group such as HMDSN is adsorbed to the quartz member, a ligand containing a methyl group (—CH₃: also simply referred to as Me) on the surface is adsorbed to the surface of the member. Here, in a case where HMDSN is supplied, for example, a ligand of —Si-Me₃ is adsorbed. Since the methyl group is also electrically negative, the methyl group repels Cl contained in Si₂Cl₆ as the source gas, and it is possible to suppress adsorption of a molecule of the source gas to the member.

Thus, in the present embodiment, the adsorption inhibiting gas that is easily adsorbed to quartz is supplied from the nozzle 430 to the UA region near the ceiling of the inner tube 204 formed of quartz, and the adsorption inhibiting component is adsorbed to the surface of the inner tube 204 exposed to the UA region. In addition, in the lower substrate-non-disposed region LA in which the seal cap 219 and the rotation shaft 255 formed of metal are arranged, the adsorption inhibiting gas that is easily adsorbed to the metal member is supplied from the nozzle 410 and the gas ejection hole 440, and the adsorption inhibiting component is adsorbed to the surfaces of the seal cap 219 and the rotation shaft 255. Here, the adsorption inhibiting component includes at least one or more of the material itself of the adsorption inhibiting gas or a part (atom, ligand) of the material of the adsorption inhibiting gas.

As a result, it is possible to suppress film formation of an unnecessary film on the inner tube 204, the seal cap 219, and the rotation shaft 255.

The adsorption inhibiting gas supply step can be performed under control of the controller 121. The adsorption inhibiting gas supply step can be performed at least one or more timings before, during, and after the processing of the wafers 200. In the processing of the wafers 200, for example, there is a case where processing of sequentially supplying a Si₂Cl₆ gas as the source gas and the NH₃ gas as the reactant gas so as not to mix them with each other is performed a predetermined number of times. During this processing, the adsorption inhibiting gas supply step can be performed. The adsorption inhibiting gas may be supplied somewhere in the middle of the processing. For example, in a case where the processing of sequentially supplying the source gas and the reactant gas is performed in cycle processing, the adsorption inhibiting gas may be supplied before (after) each cycle, or the adsorption inhibiting gas may be supplied once in a plurality of cycles. In addition, the timing before and after the processing of the wafers 200 means the timing in a state where the wafers 200 are not placed on the boat 217, but in a case where the processing of the wafers 200 is not greatly affected, the wafers 200 may be placed on the boat 217. By supplying the adsorption inhibiting gas in a state where the wafers 200 are not placed on the boat 217, it is possible to supply the adsorption inhibiting gas also to a portion of the boat 217 in contact with the wafers 200. On the other hand, it is necessary to transfer the boat 217 on which the wafers 200 are not placed into the processing container 201, which causes a problem that the overall processing speed of the substrate processing apparatus decreases.

Under the control of the controller 121, the inert gas may be supplied to the UA region and the LA region in at least one or more of the time of supplying the source gas to the process region PA and the time of supplying the reactant gas. As a result, it is possible to suppress diffusion of at least one or more of the source gas and the reactant gas into the UA region and the LA region. Specifically, when at least one or more of the source gas and the reactant gas are supplied to the gas supply pipe 352, the inert gas is supplied to at least one or more of the gas supply pipe 310 and the gas supply pipe 330.

For example, supply places (nozzles) of the adsorption inhibiting gas to be adsorbed to the inner tube 204 and the boat 217 and the adsorption inhibiting gas to be adsorbed to the metal member are preferably provided using dielectric material at places where respective members are close. As a result, by providing suppliers (nozzles) of different adsorption inhibiting gases near members including different materials, it is possible to promote adsorption of the adsorption inhibiting gas desired to be adsorbed to each of the members including different materials. Here, the dielectric material is, for example, an oxide material (SiO, AlO, or the like), a nitride material (SiN, AlN, or the like), or the like, and the metal member is SUS, Al, or the like.

Under the control of the controller 121, when the adsorption inhibiting gas is supplied to the UA region and the LA region, the inert gas may be supplied to the PA region. As a result, it is possible to suppress diffusion of the adsorption inhibiting gas into the PA region. That is, the adsorption inhibiting gas can be mainly supplied to the UA region and the LA region.

The inert gas may be supplied to the PA region from the middle of supply of the adsorption inhibiting gas. By supplying the inert gas to the PA region, it is possible to retain the adsorption inhibiting gas in the UA region and the LA region, and promote adsorption of the adsorption inhibiting component of the adsorption inhibiting gas in the regions. At a timing when the inert gas is not supplied to the PA region, the adsorption inhibiting gas is also supplied to the PA region. By supplying the adsorption inhibiting gas to the PA region, it is possible to supply also to the inner surface corresponding to the PA region of the inner tube 204 and a column of the boat 217, and adsorb the adsorption inhibiting gas to surfaces of these members. As a result, adsorption of the source gas to each part can be suppressed.

Two or more types of adsorption inhibiting gases may be prepared as the adsorption inhibiting gas, and the two or more types of adsorption inhibiting gases may be supplied simultaneously or sequentially under the control of the controller 121. As a result, it is possible to form a layer in which two or more types of adsorption inhibiting components are mixed, and it is also possible to suppress adhesion of a byproduct (by-product) generated during wafer processing and a product (ligand of the processing gas material) generated by decomposition of processing gas material in addition to suppression of adhesion of an unnecessary film.

In the above embodiment, the adsorption inhibiting gas is supplied to the UA region and the LA region, but the adsorption inhibiting gas may be supplied to the entire inner tube 204 if there is no significant influence on the processing of the wafers 200. In addition, if there is no significant influence on the processing of the wafers 200, the adsorption inhibiting gas may be supplied in a state where the wafers 200 are disposed. Here, the influence on the processing of the wafer 200 means that, for example, molecules (atom, ligand) adsorbed to the member are desorbed during the processing of the wafer 200 and taken into a film formed on the wafer 200, and the characteristics of the film formed on the wafer 200 deviate from desired film characteristics.

The controller 121 can control the APC valve 243 and the vacuum pump 246, when supply of the adsorption inhibiting gas is performed into the inner tube 204, to cause the supply to be performed in a state where an exhaust amount of the atmosphere in the inner tube 204 is set smaller than an exhaust amount at the time of processing the wafer 200. In addition, the controller 121 can control the APC valve 243 and the vacuum pump 246, when supply of the adsorption inhibiting gas is performed into the inner tube 204, to cause the supply to be performed in a state where exhaust of the atmosphere in the inner tube 204 is stopped.

As a result, a pressure of the adsorption inhibiting gas in the inner tube 204 can be increased, and the adsorption inhibiting gas can be supplied to every corner of the inner tube 204. In addition, the pressure of the adsorption inhibiting gas in the inner tube 204 increases, whereby multiple adsorption of the adsorption inhibiting gas (adsorption of a plurality of molecules at one place) can be generated and desorption of the adsorption inhibiting gas during wafer processing can be suppressed. In addition, by multiple adsorption of the adsorption inhibiting gas, even if the adsorption inhibiting gas is desorbed during wafer processing, a part of the adsorption inhibiting gas can be left, and deposition of a film can be suppressed.

Although an effect of suppressing the adsorption of the source gas to each member by supplying the adsorption inhibiting gas to each member has been described above, effects are not limited thereto. An amount of the source gas consumed in each member (an amount of the source gas adsorbed to each member) can be reduced. As a result, an amount of the source gas supplied to the wafer 200 can be increased. For example, the source gas consumed (adsorbed) by each member is supplied to the wafer 200. As a result, the processing quality of the wafer 200 can be improved. In particular, in a substrate on which a complicated uneven shape (pattern) such as a 3D device is formed, an amount of gas required for film formation is increased. According to the technique of the present disclosure, an amount of gas supplied to the wafer 200 can be increased, and quality of the film formed on the wafer 200 can be improved. In addition, in a case where a dummy substrate (dummy wafer) is placed on the boat 217, by supplying an adsorption inhibiting gas to the dummy substrate and adsorbing molecules (ligands) of the adsorption inhibiting gas to the dummy substrate, it is possible to reduce a gas consumption amount in the dummy substrate, and increase a gas supply amount to the wafer 200 to be processed.

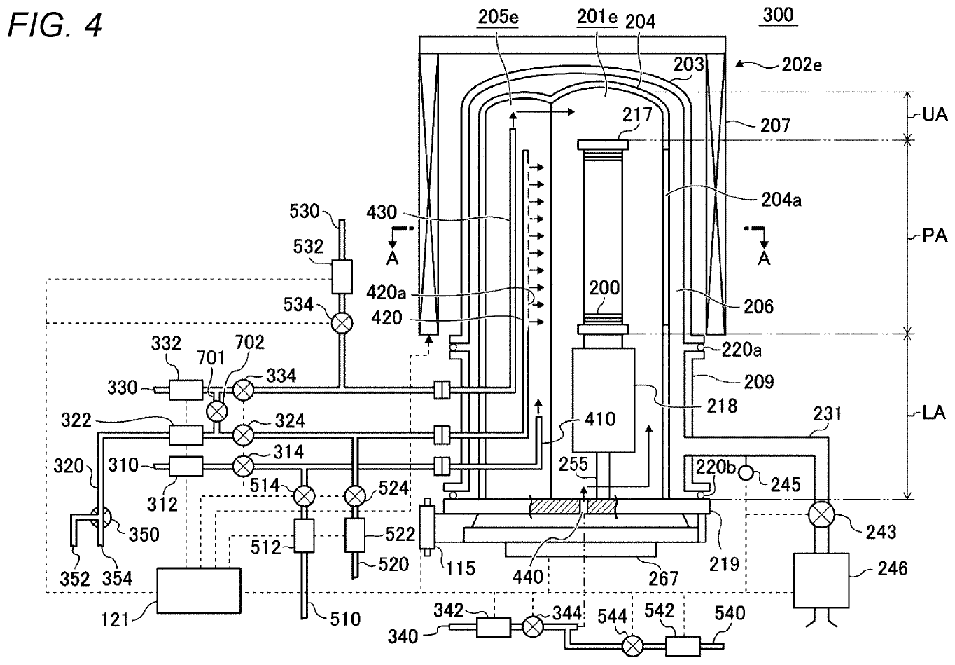

Although the example in which the adsorption inhibiting gas is supplied from the nozzle 410 and the nozzle 430 has been described above, examples are not limited thereto. The adsorption inhibiting gas may also be supplied from the nozzle 420. That is, the second supply system that supplies the adsorption inhibiting gas is also connected to the gas supply pipe 320. For example, as illustrated in FIG. 4, a gas supply pipe 701 is provided connecting the gas supply pipe 320 and the gas supply pipe 330 together, and the gas supply pipe 701 is provided with a valve 702. By opening and closing the valve 702 and the valve 334, it is possible to supply the adsorption inhibiting gas from the second supply system to the gas supply pipe 320. With such a configuration, while supplying the adsorption inhibiting gas to the PA region to supply the adsorption inhibiting gas to the inner tube 204 and the column of the boat 217, it is possible to supply the adsorption inhibiting gas also to the UA region and the LA region. In particular, in a case where the adsorption inhibiting gas is supplied from the nozzle 420, the adsorption inhibiting gas can be supplied to each of support pins supporting the wafers 200 of the boat 217, and it becomes possible to supply the adsorption inhibiting gas to each of the support pins. Furthermore, the adsorption inhibiting gas can be adsorbed inside the nozzle 420, and adsorption of the source gas into the nozzle 420 can be suppressed, that is, consumption of the source gas in the nozzle 420 can be suppressed, and the adsorption of the source gas inside the nozzle 420 is suppressed, so that reaction between the source gas adsorbed inside the nozzle 420 and the reactant gas to be supplied later can be suppressed.

In the above description, the configuration has been described in which the source gas and the reactant gas are supplied from the same gas supply pipe 320 to the processing container, but configurations are not limited thereto, and the source gas and the reactant gas may be supplied from separate nozzles. By supplying the source gas and the reactant gas from separate nozzles, it is possible to suppress reaction between one gas remaining in the nozzle and the other gas to be supplied later in the nozzle. For example, the first supplier includes a nozzle that supplies the source gas and a nozzle that supplies the reactant gas.

In the above description, an example has been described in which the NH₃ gas is used as the reactant gas, but the reactant gas is not limited thereto. For example, at least one or more hydrogen nitride-based gases can be used, such as an ammonia (NH₃) gas, a diazene (N₂H₂) gas, a hydrazine (N₂H₄) gas, and an N₃H₈ gas. By using such a gas, it is possible to form a nitride film on the wafer 200. In addition, not only the hydrogen nitride-based gas but also a gas containing oxygen can be used. As the gas containing oxygen, it is possible to use at least one or more gases of an oxygen (O₂) gas, a water (H₂O) gas, and an ozone (O₃) gas.

In the above description, the example has been described in which the processing container includes the outer tube 203, the inner tube 204, and the manifold 209, but examples are not limited thereto. For example, the outer tube 203 and the manifold 209 may be included. With such a configuration, the process chamber 201e is formed inside the outer tube 203. Even in such a case, at least one or more effects described in the present disclosure can be obtained.

### Other Embodiments

Although the embodiment of the present disclosure has been described above, the present disclosure is not limited to the above, and it is needless to say that various modifications can be made in addition to the above without departing from the gist of the present disclosure.

In the above embodiment, the substrate processing apparatus 10 of a vertical type has been described, but the present disclosure is also applicable to a single wafer type apparatus that holds the wafer 200 on a susceptor and processes the wafer one by one. For example, the upper supplier may be provided above the susceptor, and the lower supplier may be provided below the susceptor. In addition, the gas ejection hole 440 may be provided near the holding of the column that supports the susceptor.

According to the substrate processing apparatus of the present disclosure, it is possible to provide a configuration capable of suppressing film formation on a member in a processing container.

What is claimed is:

1. A substrate processing apparatus comprising:
a processing container including a first region in which a substrate is processed and a second region in which the substrate is not disposed;
a first supplier that supplies a processing gas to the first region of the processing container;
a second supplier that supplies an adsorption inhibiting gas to the second region of the processing container;
a first supply system capable of supplying the processing gas to the first supplier;
a second supply system capable of supplying the adsorption inhibiting gas to the second supplier; and
a controller capable of controlling the first supply system and the second supply system to perform:
(a) supplying the adsorption inhibiting gas to the second region; and
(b) supplying the processing gas to the first region after (a).

2. The substrate processing apparatus according to claim 1, wherein
the second region is provided above the first region.

3. The substrate processing apparatus according to claim 1, wherein
the second region is provided below the first region.

4. The substrate processing apparatus according to claim 1, wherein
the second region is provided both above and below the first region,
the second supplier includes an upper supplier that supplies the adsorption inhibiting gas to the second region provided above the first region and a lower supplier that supplies the adsorption inhibiting gas to the second region provided below the first region, and
the controller is configured to be capable of controlling the second supply system to supply the adsorption inhibiting gas to the second region above the first region and the second region below the first region in (a).

5. The substrate processing apparatus according to claim 4, wherein
the second supplier is a nozzle including an opening at a distal end, and
the nozzle is provided such that the opening is located in the upper supplier.

6. The substrate processing apparatus according to claim 4, wherein
the second supplier is a nozzle including an opening at a distal end, and
the nozzle is provided such that the opening is located in the lower supplier.

7. The substrate processing apparatus according to claim 1, wherein the first supplier includes a plurality of openings located in the first region.

8. The substrate processing apparatus according to claim 1, further comprising:
a substrate support that is provided in the processing container and supports the substrate; and
a support shaft that supports the substrate support,
wherein
the second supplier includes a support-shaft-side supplier that is disposed closer to the support shaft's side than an outer peripheral side of the second region provided below the first region and supplies the adsorption inhibiting gas to the second region.

9. The substrate processing apparatus according to claim 1, wherein
the second supply system is configured to be capable of supplying an inert gas to the second supplier, and
the controller is configured to be capable of controlling the second supply system to supply the inert gas to the second supplier in (b).

10. The substrate processing apparatus according to claim 1, wherein
the first supply system is configured to be capable of supplying an inert gas to the first supplier, and
the controller is configured to be capable of controlling the first supply system to supply the inert gas to the first supplier.

11. The substrate processing apparatus according to claim 9, wherein
the controller is configured to be capable of controlling the first supply system and the second supply system to supply the inert gas to the first region when the adsorption inhibiting gas is supplied to the second supplier.

12. The substrate processing apparatus according to claim 10, wherein
the controller is configured to be capable of controlling the first supply system and the second supply system to supply the inert gas to the first region after supplying of the adsorption inhibiting gas to the second supplier is started.

13. The substrate processing apparatus according to claim 1, wherein
the second supply system is configured to be capable of supplying the adsorption inhibiting gas to the first supplier, and
the controller is configured to be capable of controlling the second supply system to supply the adsorption inhibiting gas to the first supplier.

14. The substrate processing apparatus according to claim 1, wherein
the first supply system is capable of supplying a reactant gas to the first supplier, and
the controller is configured to be capable of controlling the first supply system and the second supply system to supply the adsorption inhibiting gas to the second region while the processing gas and the reactant gas are sequentially and repeatedly supplied in (b).

15. The substrate processing apparatus according to claim 1, wherein
the controller is configured to be capable of controlling the second supply system to perform (a) in a state where the substrate is not present in the processing container, and to perform (b) in a state where the substrate is present in the processing container.

16. The substrate processing apparatus according to claim 1, further comprising
an exhauster that exhausts an atmosphere in the processing container, wherein
the controller is configured to be capable of controlling the exhauster, when the adsorption inhibiting gas is supplied into the processing container, to exhaust the atmosphere in a state where an exhaust amount of the atmosphere is set smaller than an exhaust amount at a time of processing the substrate.

17. The substrate processing apparatus according to claim 1, further comprising
an exhauster that exhausts an atmosphere in the processing container, wherein
the controller is configured to be capable of controlling the exhauster, when the adsorption inhibiting gas is supplied into the processing container, to exhaust the atmosphere in a state where exhaust of the atmosphere is stopped.

18. A substrate processing method comprising:
(a) supplying an adsorption inhibiting gas to a second region of a processing container including a first region in which a substrate is processed and the second region in which the substrate is not disposed; and
(b) supplying a processing gas to the first region after (a).

19. A method of manufacturing a semiconductor device, comprising the method of claim 18.

20. A non-transitory computer-readable recording medium that causes, by a computer, a substrate processing apparatus to perform:
(a) supplying an adsorption inhibiting gas to a second region of a processing container including a first region in which a substrate is processed and the second region in which the substrate is not disposed; and
(b) supplying a processing gas to the first region after (a) to process the substrate disposed in the first region.
